(19) United States
(12) Patent Application Publication
(10) Pub. No.: US 2024/0203726 A1
(43) Pub. Date: Jun. 20, 2024

(54) ORGANIC SOLVENT SUPPLYING APPARATUS, SUBSTRATE PROCESSING METHOD, AND SUBSTRATE PROCESSING APPARATUS

(71) Applicant: SEMES CO., LTD., Cheonan-si (KR)

(72) Inventors: Myung Seok CHA, Seoul (KR); Ki Bong KIM, Paju-si (KR); Yong Hyun CHOI, Cheonan-si (KR); Ju Yeon SONG, Sokcho-si (KR)

(73) Assignee: SEMES CO., LTD., Cheonan-si (KR)

(21) Appl. No.: 18/241,893

(22) Filed: Sep. 3, 2023

(30) Foreign Application Priority Data
Dec. 19, 2022 (KR) 10-2022-0178389

(51) Int. Cl. H01L 21/02; H01L 21/67; H01L 21/677

(52) U.S. Cl. CPC H01L 21/02101; H01L 21/02057; H01L 21/67034; H01L 21/67748; H01L 21/6776

(57) ABSTRACT

Proposed are an organic solvent supplying apparatus, a substrate processing method, and a substrate processing apparatus. An organic solvent supplying apparatus according to an embodiment supplies an organic solvent to a liquid processing chamber of a substrate processing apparatus, the substrate processing apparatus including the liquid processing chamber for supplying the organic solvent to a substrate and a supercritical processing chamber for drying the substrate coated with the organic solvent using supercritical fluid. The organic solvent supplying apparatus includes a supply tank for storing the organic solvent, a supply line connected to the supply tank and the liquid processing chamber, and a cooling module provided on the supply line.

### CROSS-REFERENCE TO RELATED APPLICATION

This Patent application claims priority to Korean Patent Application No. 10-2022-0178389, filed on Dec. 19, 2022, the entire contents of which are incorporated by reference herein for all purposes.

### BACKGROUND

### Field of the Invention

The present disclosure relates to an organic solvent supplying apparatus for supplying an organic solvent for processing a substrate, a substrate processing method, and a substrate processing apparatus.

### Description of the Related Art

A semiconductor manufacturing process is a process for the manufacture of a semiconductor device on a substrate (e.g., a wafer). The process includes, for example, exposure, deposition, etching, ion implantation, cleaning, and the like. In order to perform each manufacturing process, various semiconductor manufacturing equipment is provided in a clean room of a semiconductor manufacturing plant. A substrate fed into each semiconductor manufacturing equipment is processed through a corresponding process.

Since various processing liquids and processing gases are used in each process, particles and by-products are generated during the process. To remove these particles and by-products from the substrate, a cleaning process is performed before and after each process.

In a conventional cleaning process, the substrate is processed with a chemical and a rinse liquid and then dried. As an example of the drying process, there is a spin-drying process in which the substrate is rotated at high speed to remove the rinse liquid remaining on the substrate. However, this spin-drying method may cause collapsing of a pattern formed on the substrate.

As a solution to this problem, there has been proposed a supercritical drying process involving the use of a supercritical fluid. An organic solvent having a lower surface tension than the rinse liquid, such as isopropyl alcohol (IPA), is supplied onto the substrate to replace the rinse liquid remaining on the substrate with the organic solvent. After that, a processing fluid in a supercritical state is supplied onto the substrate to remove the organic solvent remaining on the substrate. In the supercritical drying process, a drying gas is heated and pressurized in a sealed process chamber. As the temperature and pressure of the drying gas rise above the critical points, the drying gas undergoes a phase change to a supercritical state.

Meanwhile, with the miniaturization of the semiconductor manufacturing process, there is an increasing demand for removing particles generated in the substrate processing process. In particular, since the substrate may be rather contaminated by chemicals used in the cleaning process including supercritical drying, an urgent need exists for a technology that can prevent contamination of the substrate.

The foregoing is intended merely to aid in the understanding of the background of the present disclosure, and is not intended to mean that the present disclosure falls within the purview of the related art that is already known to those skilled in the art.

### SUMMARY

Accordingly, the present disclosure has been made keeping in mind the above problems occurring in the related art, and an objective of the present disclosure is to provide an organic solvent supplying apparatus, a substrate processing method, and a substrate processing apparatus that can prevent a substrate from being contaminated by an organic solvent.

In order to achieve the above objective, according to one aspect of the present disclosure, there is provided an organic solvent supplying apparatus for supplying an organic solvent to a liquid processing chamber of a substrate processing apparatus, the substrate processing apparatus including the liquid processing chamber configured to supply the organic solvent to a substrate and a supercritical processing chamber configured to dry the substrate coated with the organic solvent using supercritical fluid. The organic solvent supplying apparatus may include: a supply tank configured to store the organic solvent; a supply line connected to the supply tank and the liquid processing chamber; and a cooling module provided on the supply line.

Furthermore, the organic solvent may include isopropyl alcohol (IPA).

Furthermore, the IPA may be supplied to the liquid processing chamber at a temperature in the range of −89° C. to 0° C.

Furthermore, the supply line may connect the supply tank and a nozzle of the liquid processing chamber to each other, and the cooling module may be provided near the supply tank on the supply line.

Furthermore, the cooling module may include: a heat exchanger configured to cool a temperature of the organic solvent to equal to or less than a predetermined temperature using a coolant; and a chiller configured to supply the coolant to the heat exchanger.

Furthermore, the cooling module may further include a temperature controller configured to control a flow rate of the coolant supplied to the heat exchanger.

Furthermore, the temperature controller may control the flow rate of the coolant on the basis of the temperature of the organic solvent supplied to the substrate.

Furthermore, the temperature of the organic solvent may be measured by a temperature sensor provided in the nozzle.

Furthermore, the organic solvent supplied in a cooled state may be dissolved by a supercritical fluid in the supercritical processing chamber.

According to another aspect of the present disclosure, there is provided a substrate processing method performed by a substrate processing apparatus, the substrate processing method including: supplying an organic solvent from a liquid processing chamber to a substrate; transferring the substrate coated with the organic solvent to a supercritical processing chamber; and supplying a supercritical fluid for drying the organic solvent to the substrate in the supercritical processing chamber. The organic solvent may be supplied to the substrate in a state of being cooled by a cooling module.

Furthermore, the cooling module may be provided on a supply line connected to a supply tank for storing the organic solvent and the liquid processing chamber.

Furthermore, the substrate coated with the organic solvent may be transferred from the liquid processing chamber to the supercritical processing chamber by a transfer robot.

According to another aspect of the present disclosure, there is provided a substrate processing apparatus including: a liquid processing chamber configured to supply an organic solvent for cleaning a substrate to the substrate; a transfer robot configured to transfer the substrate coated with the organic solvent; a supercritical processing chamber configured to supply a supercritical fluid for drying the substrate coated with the organic solvent; and an organic solvent supplying apparatus configured to supply the organic solvent to the liquid processing chamber. The organic solvent supplying apparatus may include: a supply tank configured to store the organic solvent; a supply line connected to the supply tank and the liquid processing chamber; and a cooling module provided on the supply line.

According to the organic solvent supplying apparatus, the substrate processing method, and the substrate processing apparatus according to the embodiment of the present disclosure, by enabling the organic solvent to be supplied in a state in which it is cooled to equal to or less than a predetermined temperature, it is possible to prevent contamination of the substrate.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating the layout of a substrate processing apparatus according to the present disclosure;

FIG. 2 is a view illustrating a simplified configuration of the substrate processing apparatus;

FIG. 3 is a view schematically illustrating the configuration of a liquid processing chamber in the substrate processing apparatus according to the present disclosure;

FIG. 4 is a view schematically illustrating the configuration of a supercritical processing chamber in the substrate processing apparatus according to the present disclosure;

FIG. 5 is a view illustrating the configuration of an organic solvent supplying apparatus according to the present disclosure; and

FIG. 6 is a flowchart illustrating a substrate processing method according to the present disclosure.

### DETAILED DESCRIPTION

Hereinafter, exemplary embodiments of the present disclosure will be described in detail with reference to the accompanying drawings.

In the following description, a detailed description of related known configurations or functions may be omitted to avoid obscuring the subject matter of the present disclosure.

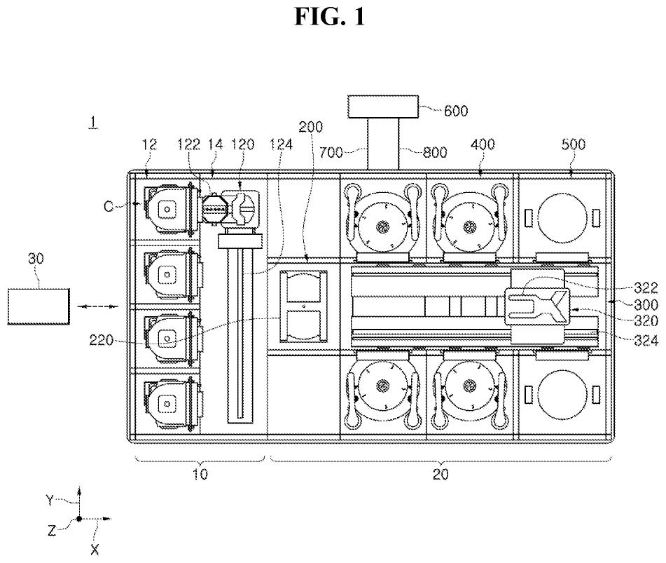

FIG. 1 is a view illustrating the layout of a substrate processing apparatus 1 according to the present disclosure. Referring to FIG. 1, the substrate processing apparatus 1 may include an index module 10, a processing module 20, and a controller 30. When viewed from above, the index module 10 and the processing module 20 may be disposed along one direction. Hereinafter, a direction in which the index module 10 and the processing module 20 are disposed is referred to as a first direction X, a direction orthogonal to the first direction X when viewed from above is referred to as a second direction Y, and a direction orthogonal to both the first direction X and the second direction Y is referred to as a third direction Z.

The index module 10 may transfer a substrate W from a container C in which the substrate W is stored to the processing module 20, and transfer the substrate W processed in the processing module 20 to the container C. The index module 10 may be disposed such that a longitudinal direction thereof corresponds to the second direction Y. The index module 10 may include a load port 12 and an index frame 14. The load port 12 may be located on the opposite side of the processing module 20 with respect to the index frame 14. The container C in which a plurality of substrates W are stored may be placed on the load port 12. A plurality of load ports 12 may be provided. The load ports 12 may be disposed along the second direction Y.

As the container C, a sealing container such as a front opening unified pod (FOUP) may be used. The container C may be placed on the load port 12 by an operator or a transport means (not illustrated) such as an overhead transfer, an overhead conveyor, or an automatic guided vehicle.

The index frame 14 may be provided with an index robot 120. A guide rail 124 may be provided in the index frame 14. The guide rail 124 may be disposed such that a longitudinal direction thereof corresponds to the second direction Y. The index robot 120 may be configured to be moved on the guide rail 124. The index robot 120 may include a hand 122 on which the substrate W is placed. The hand 122 may be configured to be moved forward and backward, axially rotated in the third direction Z, and moved along the third direction Z. A plurality of hands 122 may be provided to be spaced apart from each other along a vertical direction. The hands 122 may be configured to be moved forward and backward independently of each other.

The controller 30 may control the substrate processing apparatus 1. The controller 30 may include a process controller provided with a micro-processor (computer) which controls the substrate processing apparatus 1; a user interface provided with a keyboard through which an operator inputs operation commands for managing the substrate processing apparatus 1, or a display which displays the operation of the substrate processing apparatus 1; and a memory unit which stores a control program to realize the control of processing performed at the substrate processing apparatus 1, or a processing recipe which is a program for performing processing for each component of the substrate processing apparatus 1 on the basis of various data and processing conditions. Also, the user interface and the memory unit may be connected to the process controller. The processing recipe may be stored at a storage medium of the memory unit. The storage medium may be a hard disk, a portable disk such as a CD-ROM or a DVD, or a semiconductor memory such as a flash memory.

The processing module 20 may include a buffer unit 200, a transfer chamber 300, a liquid processing chamber 400, and a supercritical processing chamber 500. The buffer unit 200 may provide a space in which the substrate W transferred into the processing module 20 and the substrate W transferred out of the processing module 20 temporarily stay. The liquid processing chamber 400 may perform a liquid processing process of liquid-processing the substrate W by supplying a liquid onto the substrate W. The supercritical processing chamber 500 may perform a drying process of removing the liquid remaining on the substrate W. The transfer chamber 300 may transfer the substrate W between the buffer unit 200, the liquid processing chamber 400, and the supercritical processing chamber 500. Meanwhile, an organic solvent supplying apparatus 600 may be connected to the liquid processing chamber 400 through a supply line 700 and a recovery line 800. The organic solvent supplying apparatus 600 may supply an organic solvent for rinsing the substrate W through the supply line 700 and recover the organic solvent from the liquid processing chamber 400 through the recovery line 800.

The transfer chamber 300 may be disposed such that a longitudinal direction thereof corresponds to the first direction X. The buffer unit 200 may be disposed between the index module 10 and the transfer chamber 300. The liquid processing chamber 400 and the supercritical processing chamber 500 may be disposed on a side of the transfer chamber 300. The liquid processing chamber 400 and the transfer chamber 300 may be disposed along the second direction Y. The supercritical processing chamber 500 and the transfer chamber 300 may be disposed along the second direction Y. The buffer unit 200 may be located at one end of the transfer chamber 300.

According to an embodiment, a plurality of liquid processing chambers 400 may be disposed on each side of the transfer chamber 300, a plurality of supercritical processing chambers 500 may be disposed on each side of the transfer chamber 300, and the liquid processing chambers 400 may be disposed closer to the buffer unit 200 than the supercritical processing chambers 500. On a first side of the transfer chamber 300, the liquid processing chambers 400 may be disposed in an arrangement of A×B (where A and B are each 1 or a natural number greater than 1) along the first direction X and the third direction Z. In addition, On the first side of the transfer chamber 300, the supercritical processing chambers 500 may be disposed in an arrangement of C×D (where C and D are each 1 or a natural number greater than 1) along the first direction X and the third direction Z. Unlike the above description, only the liquid processing chambers 400 may be provided on the first side of the transfer chamber 300, and only the supercritical processing chambers 500 may be provided on the second side of the transfer chamber 300. Meanwhile, the organic solvent supplying apparatus 600 for supplying a processing liquid (organic solvent) to the liquid processing chambers 400 may be configured as a part of the substrate processing apparatus 1. The organic solvent supplying apparatus 600 may supply the organic solvent through the supply line 700 and recover the organic solvent through the recovery line 800.

The transfer chamber 300 may be provided with a transfer robot 320. A guide rail 324 may be provided in the transfer chamber 300. The guide rail 324 may be disposed such that a longitudinal direction thereof corresponds to the first direction X. The transfer robot 320 may be configured to be moved on the guide rail 324. The transfer robot 320 may include a hand 322 on which the substrate W is placed. The hand 322 may be configured to be moved forward and backward, axially rotated in the third direction Z, and moved along the third direction Z. A plurality of hands 322 may be provided to be spaced apart from each other along a vertical direction. The hands 322 may be configured to be moved forward and backward independently of each other.

The buffer unit 200 includes a plurality of buffers 220 on which the substrates W are placed. The buffers 220 may be disposed to be spaced apart from each other along the third direction Z. The buffer unit 200 may have open front and rear faces. The front face may be a surface facing the index module 10, and the rear face may be a surface facing the transfer chamber 300. The index robot 120 may approach the buffer unit 200 through the front face, and the transfer robot 320 may approach the buffer unit 200 through the rear face.

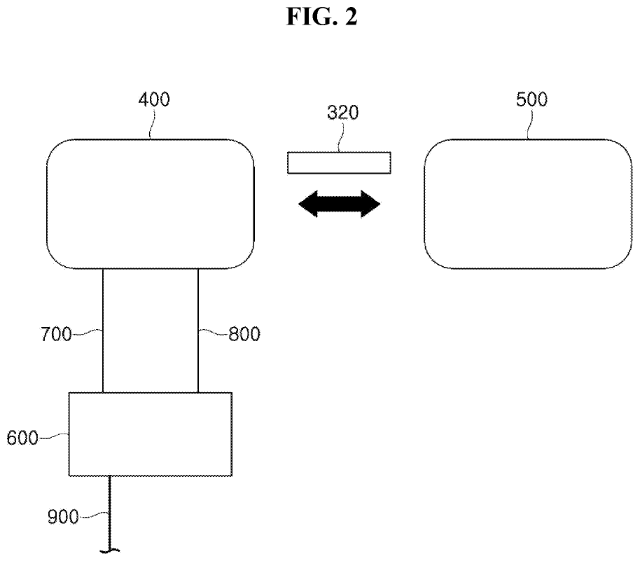

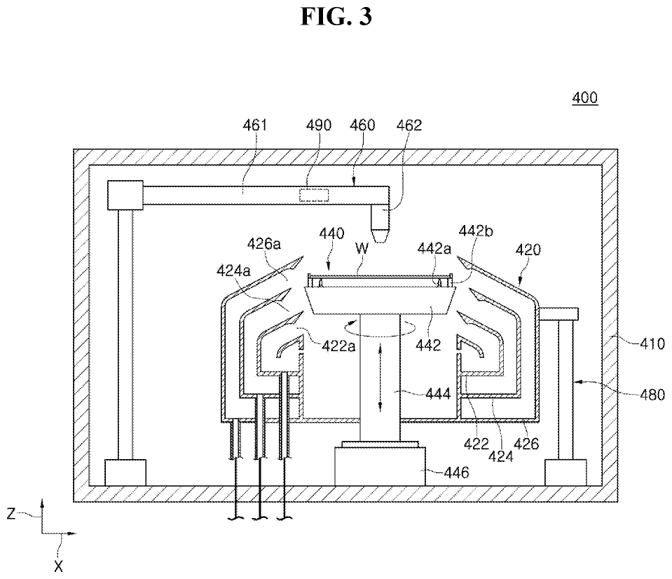

FIG. 2 is a view illustrating a simplified configuration of the substrate processing apparatus 1. According to the present disclosure, the substrate processing apparatus 1 may include the liquid processing chamber 400 for supplying a cleaning liquid for cleaning processing, a rinse liquid, and the organic solvent which replaces the rinse liquid to remove foreign substances remaining on the substrate W to the substrate W; the transfer robot 320 for transferring the substrate W coated with the organic solvent; the supercritical processing chamber 500 for supplying a supercritical fluid for drying the organic solvent; and the organic solvent supplying apparatus 600 for supplying the organic solvent to the liquid processing chamber 400. The organic solvent supplying apparatus 600 may supply the organic solvent through the supply line 700 and recover the organic solvent through the recovery line 800. The organic solvent used in the liquid processing chamber 400 may be discharged to the outside through a discharge line 850. The liquid processing chamber 400, the supercritical processing chamber 500, and the organic solvent supplying apparatus 600 will be described with reference to FIGS. 3 to 6 below.

FIG. 3 is a view illustrating the configuration of the liquid processing chamber 400 according to the present disclosure. FIG. 3 illustrates an embodiment of the liquid processing chamber 400 in the substrate processing apparatus illustrated in FIGS. 1 and 2. Referring to FIG. 3, the liquid processing chamber 400 may include a housing 410, a cup 420, a support unit 440, a liquid supply unit 460, and a lifting unit 480.

The housing 410 may have an inner space in which the substrate W is processed. The housing 410 may have a substantially hexahedral shape. The housing 410 may have, for example, a rectangular parallelepiped shape. In addition, an opening (not illustrated) through which the substrate W is loaded or unloaded may be formed in the housing 410. In addition, a door (not illustrated) for selectively opening and closing the opening may be installed in the housing 410.

The cup 420 may have a cylindrical shape with an open top. The cup 420 may have a processing space. The substrate W may be liquid-processed in the processing space. The support unit 440 may support the substrate W in the processing space. The liquid supply unit 460 may supply a processing liquid onto the substrate W supported by the support unit 440. A plurality of types of processing liquids may be provided. The processing liquids may be sequentially supplied onto the substrate W. The lifting unit 480 may adjust a relative height between the cup 420 and the support unit 440.

According to an embodiment, the cup 420 may include a plurality of recovery tubs 422, 424, and 426. Each of the recovery tubs 422, 424, and 426 may have a recovery space for recovering a liquid used in processing of the substrate W. Each of the recovery tubs 422, 424, and 426 may be provided in a ring shape surrounding the support unit 440. During the liquid processing process, the processing liquid scattered by rotation of the substrate W may flow into the recovery spaces through respective inlets 422a, 424a, and 426a of the recovery tubs 422, 424, and 426. According to an embodiment, the cup 420 may include a first recovery tub 422, a second recovery tub 424, and a third recovery tub 426. The first recovery tub 422 may be disposed to surround the support unit 440, the second recovery tub 424 may be disposed to surround the first recovery tub 422, and the third recovery tub 426 may be disposed to surround the second recovery tub 424. The second inlet 424a through which the liquid flows into the second recovery tub 424 may be located higher than the first inlet 422a through which the liquid flows into the first recovery tub 422, and the third inlet 426a through which the liquid flows into the third recovery tub 426 may be located higher than the second inlet 424a.

The support unit 440 may include a support plate 442 and an actuating shaft 444. An upper surface of the support plate 442 may be provided in a substantially circular shape and may have a larger diameter than the substrate W. A plurality of support pins 442a for supporting a lower surface of the substrate W may be provided at top surface of the support plate 442. An upper end of each of the support pins 442a may protrude from the support plate 442 so that the substrate W is spaced apart from the support plate 442 by a predetermined distance. A plurality of chuck pins 442b may be provided at the edge of the support plate 442. The chuck pins 442b may protrude upward from the support plate 442. The chuck pins 442b may support lateral side portions of the substrate W so as to prevent the substrate W from being separated from the support unit 440 when the substrate W is rotated. The actuating shaft 444 may be driven by an actuator 446. The actuating shaft 444 may be connected to the center of the lower surface of the substrate W, and may rotate the support plate 442 about the central axis thereof.

According to an embodiment, the liquid supply unit 460 may include a nozzle 462 for discharging the processing liquid and an arm 461 for supporting and moving the nozzle 462. The nozzle 462 may supply the processing liquid onto the substrate W. The processing liquid may be a chemical, a rinse liquid, or an organic solvent. The chemical may be a liquid having strong acidic or strong basic properties. The rinse liquid may be pure water. The organic solvent may be isopropyl alcohol (IPA). In addition, the liquid supply unit 460 may include a plurality of nozzles 462. The nozzles 462 may supply different types of processing liquids. For example, one of the nozzles 462 may supply the chemical, another one of the nozzles 462 may supply the rinse liquid, and still another one of the nozzles 462 may supply the organic solvent. In addition, the controller 30 may control the liquid supply unit 460 to supply the rinse liquid to the substrate W from another one of the nozzles 462 and then supply the organic solvent to the substrate W from still another one of the nozzles 462. Thus, the rinse liquid supplied onto the substrate W may be replaced with the organic solvent having a lower surface tension than the rinse liquid. Meanwhile, a temperature sensor 490 for measuring the temperature of the processing liquid (organic solvent) supplied to the substrate W may be provided in the nozzle 462.

The lifting unit 480 may move the cup 420 upward and downward. The vertical movement of the cup 420 may allow the relative height between the cup 420 and the substrate W to be changed. Thus, depending on the type of processing liquid supplied to the substrate W, the recovery tubs 422, 424, and 426 may be selectively positioned relative to the substrate W so that each processing liquid is recovered separately. Unlike the above description, the cup 420 may be fixedly installed, and the lifting unit 480 may move the support unit 440 upward and downward.

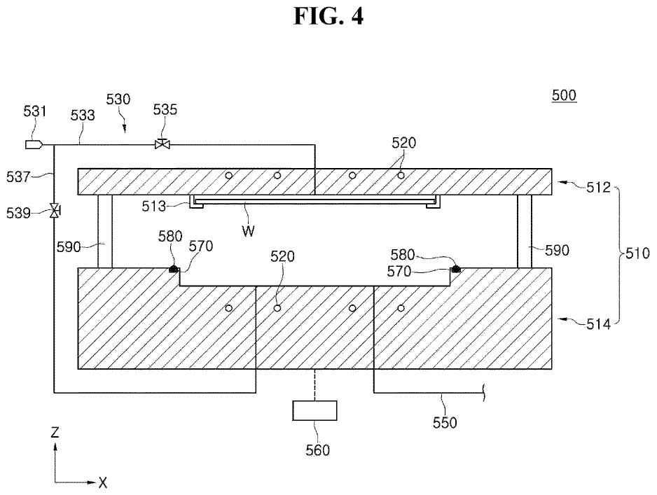

FIG. 4 is a view illustrating the configuration of the supercritical processing chamber 500 according to the present disclosure. FIG. 4 illustrates an embodiment of the supercritical processing chamber 500 in the substrate processing apparatus illustrated in FIGS. 1 and 2.

Referring to FIG. 4, the supercritical processing chamber 500 according to the embodiment of the present disclosure may remove the processing liquid remaining on the substrate W by using a drying fluid in a supercritical state. For example, the supercritical processing chamber 500 may perform the drying process of removing the organic solvent remaining on the substrate W by using carbon dioxide (CO2) in a supercritical state.

A vessel member 510 may include an upper body 512 (an example of a first body) and a lower body 514 (an example of a second body). The upper body 512 and the lower body 514 may be coupled to each other to form a processing space in which the substrate W is processed. The substrate W may be supported in the processing space. For example, the substrate W may be supported by a support member 513 in the processing space. The support member 513 may support the edge of the lower surface of the substrate W. Any one of the upper body 512 and the lower body 514 may be coupled to a moving member 560 and moved upward and downward (third direction Z). For example, the lower body 514 may be coupled to the moving member 560 and moved upward and downward along actuating shafts 590 by the moving member 560. Thus, the processing space of the vessel member 510 may be selectively sealed. Although it has been described in the above example that the lower body 514 is coupled to the moving member 560 and moved upward and downward, but the present disclosure is not limited thereto. For example, the upper body 512 may be coupled to the moving member 560 and moved upward and downward.

A heating member 520 may heat the drying fluid supplied into the processing space. The heating member 520 may increase the temperature of the processing space of the vessel member 510 to change the phase of the drying fluid supplied to the processing space to a supercritical state. In addition, the heating member 520 may increase the temperature of the processing space of the vessel member 510 so that the drying fluid supplied to the processing space is maintained in the supercritical state.

In addition, the heating member 520 may be embedded in the vessel member 510. For example, the heating member 520 may be embedded in any one of the upper body 512 and the lower body 514. For another example, the heating member 520 may be provided in each of the upper body 512 and the lower body 514. However, the present disclosure is not limited thereto, and the heating member 520 may be provided at various positions capable of increasing the temperature of the processing space. In addition, the heating member 520 may be a heater. However, the present disclosure is not limited thereto, and the heating member 520 may be embodied as various known devices capable of increasing the temperature of the processing space.

A fluid supply member 530 may supply the drying fluid (supercritical fluid) to the processing space of the vessel member 510. The drying fluid supplied by the fluid supply member 530 may include carbon dioxide (CO2). The fluid supply member 530 may include a fluid supply source 531, a first supply line 533, a first supply valve 535, a second supply line 537, and a second supply valve 539.

The fluid supply source 531 may store and/or supply the drying fluid supplied to the processing space of the vessel member 510. The fluid supply source 531 may supply the drying fluid to the first supply line 533 and/or the second supply line 537. For example, the first supply valve 535 may be installed on the first supply line 533. In addition, the second supply valve 539 may be installed on the second supply line 537. The first supply valve 535 and the second supply valve 539 may be on/off valves. The drying fluid may selectively flow through the first supply line 533 or the second supply line 537 according to an on/off operation of the first supply valve 535 and the second supply valve 539.

Although it has been described in the above example that the first supply line 533 and the second supply line 537 are connected to one fluid supply source 531, the present disclosure is not limited thereto. For example, a plurality of fluid supply sources 531 may be provided. Here, the first supply line 533 may be connected to any one of the fluid supply sources 531, and the second supply line 537 may be connected to another one of the fluid supply sources 531.

In addition, the first supply line 533 may be an upper supply line which supplies a drying gas from the top of the processing space of the vessel member 510. For example, the first supply line 533 may supply the drying gas to the processing space of the vessel member 510 in a direction from the top to the bottom of the processing space. For example, the first supply line 533 may be connected to the upper body 512. In addition, the second supply line 537 may be a lower supply line which supplies the drying gas from the bottom of the processing space of the vessel member 510. For example, the second supply line 537 may supply the drying gas to the processing space of the vessel member 510 in a direction from the bottom to the top of the processing space. For example, the second supply line 537 may be connected to the lower body 514.

A fluid exhaust line 550 may exhaust the drying fluid from the processing space of the vessel member 510. The fluid exhaust line 550 may be connected to a pressure reducing member (not illustrated) which provides pressure to the processing space. The pressure reducing member may be a pump. However, it is not limited thereto, and the pressure reducing member may be embodied as various known devices capable of providing pressure to the processing space.

The processing space formed by coupling the upper body 512 and the lower body 514 described above may be maintained at a high pressure while processing the substrate W. To this end, the supercritical processing chamber 500 may include a sealing member 580 for maintaining airtightness of the processing space formed by the upper body 512 and the lower body 514. The sealing member 580 may be disposed between the upper body 512 and the lower body 514. The sealing member 580 may be inserted into a groove 570 formed in the vessel member 510. For example, the groove 570 into which the sealing member 580 is inserted may be formed in the lower body 514.

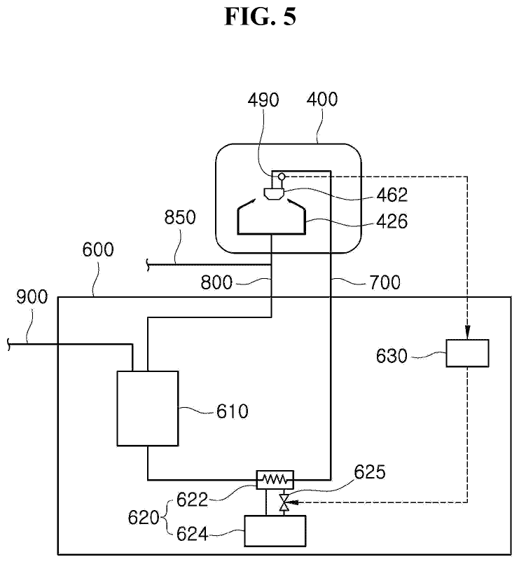

FIG. 5 is a view illustrating the configuration of the organic solvent supplying apparatus 600 according to the present disclosure. The organic solvent supplying apparatus 600 may supply the organic solvent to the liquid processing chamber 400. The organic solvent may be used for rinsing the substrate W.

The organic solvent supplying apparatus 600 may include a supply tank 610 for storing the organic solvent, the supply line 700 connected to the supply tank 610 and the liquid processing chamber 400, and a cooling module 620 provided on the supply line 700. The cooling module 620 may cool the organic solvent supplied from the supply tank 610 to the liquid processing chamber 400. The supply tank 610 may be configured as a container for storing the organic solvent. The organic solvent may be stored in the supply tank 610 by flowing into the supply tank 610 through a replenishment line 900. The supply tank 610 may be configured as a sealed container to store the organic solvent. The supply tank 610 may store the organic solvent while circulating the organic solvent through a circulation line (not illustrated). The organic solvent may be supplied from the supply tank 610 to the liquid processing chamber 400 through the supply line 700. The organic solvent may be isopropyl alcohol (IPA) having high volatility. The supply line 700 may connect the supply tank 610 and the nozzle 462 of the liquid processing chamber 400 to each other. The cooling module 620 may be provided near the supply tank 610 on the supply line 700.

Meanwhile, the applicant of the present disclosure found that, as a result of applying an organic solvent having a temperature equal to or higher than room temperature to the substrate W and then drying the organic solvent using the supercritical fluid, the higher the temperature of the organic solvent, the more the organic solvent acts as a particle source of the substrate W. That is, it was confirmed that the number of particles on the substrate W increases as the temperature of the organic solvent increases. It is speculated that this is because the high-temperature organic solvent reacts with foreign substances in a pipe while flowing along the supply line 700 due to high reactivity thereof, or the organic solvent itself is transformed as the temperature thereof increases. Thus, supplying the organic solvent at a reduced temperature may be a countermeasure for reducing particles on the substrate W. In view of this, the applicant of the present disclosure has devised a method of cooling and supplying the organic solvent supplied to the liquid processing chamber 400.

Since the organic solvent supplying apparatus 600 according to the embodiment of the present disclosure supply the organic solvent after cooling it below a predetermined temperature, an increased intermolecular attraction between organic solvent molecules may prevent the organic solvent from flowing by inertia and reduce the amount of evaporation of the organic solvent. Thus, the organic solvent may be uniformly applied to the substrate W.

The organic solvent supplying apparatus 600 according to the present disclosure may include the cooling module 620 for cooling the organic solvent supplied from the supply tank 610 to the liquid processing chamber 400. The cooling module 620 may reduce particles generated on the substrate W by cooling the organic solvent supplied to the liquid processing chamber 400. The organic solvent may include isopropyl alcohol (IPA). IPA may be supplied to the liquid processing chamber 400 at a temperature in the range of −89° C. to 0° C. In the case of using a spin-drying method rather than a supercritical drying method, it is advantageous to supply IPA at a high temperature. However, in the case of using the supercritical drying method, it is not necessary to supply IPA at a high temperature, but rather, supplying IPA at a low temperature is advantageous for reducing particles. Here, −89° C. may be a temperature corresponding to the freezing point of IPA.

The cooling module 620 may be provided on the supply line 700 connecting the supply tank 610 and the liquid processing chamber 400 to each other. The cooling module 620 may cool the organic solvent flowing into the liquid processing chamber 400 through the supply line 700 to a temperature equal to or less than a predetermined temperature.

The cooling module 620 may include a heat exchanger 622 for cooling the temperature of the organic solvent to equal to or less than a predetermined temperature using a coolant, and a chiller 624 for supplying the coolant to the heat exchanger 622. The chiller 624 may provide the coolant for cooling the organic solvent to the heat exchanger 622, and the heat exchanger 622 may cool the organic solvent by allowing heat of the organic solvent to be transferred to the coolant. The chiller 624 may be provided inside the organic solvent supplying apparatus 600 or outside the organic solvent supplying apparatus 600.

In addition, the cooling module 620 may include a temperature controller 630 for controlling the flow rate of the coolant supplied to the heat exchanger 622. The temperature controller 630 may control the flow rate of the coolant on the basis of the temperature of the organic solvent supplied to the substrate W. Referring to FIG. 5, the temperature sensor 490 may be provided in the nozzle 462 (or a pipe of the arm 461) for supplying the organic solvent to the substrate W. The temperature sensor 490 may measure the temperature of the organic solvent supplied to the substrate W. Since the temperature of the organic solvent may change while it flows along the pipe, the temperature controller 630 may adjust the degree of cooling the organic solvent while checking a change in the temperature of the organic solvent so that the organic solvent is cooled to an appropriate level. The organic solvent supplied to the substrate W may be recovered by the third recovery tub 426 and discharged to the outside through the discharge line 850, or may be recovered to the supply tank 610 through the recovery line 800. In FIG. 5, the temperature of the organic solvent supplied to the substrate W may be measured by the temperature sensor 490 provided in the nozzle 462 and provided to the temperature controller 630. The temperature controller 630 may control a flow control valve 625 for adjusting the flow rate of the coolant supplied from the chiller 624 to the heat exchanger 622 according to the received temperature of the organic solvent.

The substrate W coated with the organic solvent supplied in a cooled state may be transferred to the supercritical processing chamber 500, and then the drying process using the supercritical fluid may be performed by the supercritical processing chamber 500. That is, the organic solvent supplied to the substrate W in a cooled state by the cooling module 620 may be dissolved by the supercritical fluid.

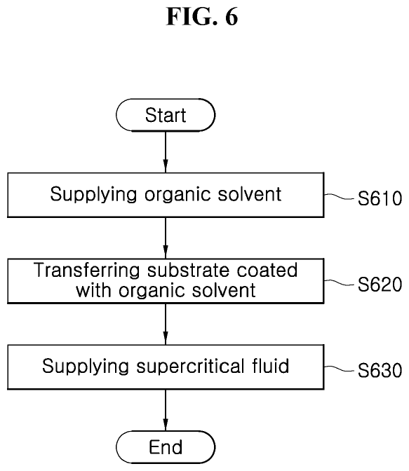

FIG. 6 is a flowchart illustrating a substrate processing method according to the present disclosure. The substrate processing method performed by the substrate processing apparatus 1 according to the present disclosure may include: supplying an organic solvent from a liquid processing chamber 400 to a substrate W (S610); transferring the substrate W coated with the organic solvent to a supercritical processing chamber 500 (S620); and supplying a supercritical fluid for drying the organic solvent from the supercritical processing chamber 500 to the substrate W (S630).

More specifically, a process of cleaning the substrate W may include: supplying a chemical having strong acidic or strong basic properties for cleaning the substrate W; supplying a rinse liquid (e.g., pure water) for rinsing the chemical; supplying an organic solvent to replace the rinse liquid; and drying the organic solvent using supercritical fluid.

The organic solvent may be supplied to the substrate W in a state of being cooled to equal to or less than a predetermined temperature by a cooling module 620. The organic solvent may include isopropyl alcohol (IPA). IPA may be supplied to the liquid processing chamber 400 at a temperature in the range of −89° C. to 0° C. The cooling module 620 may be connected to a supply tank 610 for storing the organic solvent and the liquid processing chamber 400.

The supply of the organic solvent may be performed in the liquid processing chamber 400, and the supply of the supercritical fluid may be performed in the supercritical processing chamber 500. That is, the substrate W coated with the organic solvent may be transferred from the liquid processing chamber 400 to the supercritical processing chamber 500 by a transfer robot 320, and then dried by the supercritical fluid in the supercritical processing chamber 500.

While the description of the organic solvent supplying apparatus, the substrate processing method, and the substrate processing apparatus according to the present disclosure has been made to the exemplary embodiments, it will be appreciated to those skilled in the art that various changes and modifications may be made without departing from the scope of the present disclosure. The embodiment of the present disclosure is not limited thereto. Therefore, the scope of the present disclosure should be defined by the appended claims rather than by the foregoing embodiments.

What is claimed is:

1. An organic solvent supplying apparatus for supplying an organic solvent to a liquid processing chamber of a substrate processing apparatus, the substrate processing apparatus comprising the liquid processing chamber configured to supply the organic solvent to a substrate and a supercritical processing chamber configured to dry the substrate coated with the organic solvent using supercritical fluid, the organic solvent supplying apparatus comprising:
a supply tank configured to store the organic solvent;
a supply line connected to the supply tank and the liquid processing chamber; and
a cooling module provided on the supply line.

2. The organic solvent supplying apparatus of claim 1, wherein the organic solvent comprises isopropyl alcohol (IPA).

3. The organic solvent supplying apparatus of claim 2, wherein the IPA is supplied to the liquid processing chamber at a temperature in a range of −89° C. to 0° C.

4. The organic solvent supplying apparatus of claim 1, wherein the supply line connects the supply tank and a nozzle of the liquid processing chamber to each other, and
the cooling module is provided near the supply tank on the supply line.

5. The organic solvent supplying apparatus of claim 4, wherein the cooling module comprises:
a heat exchanger configured to cool a temperature of the organic solvent to equal to or less than a predetermined temperature using a coolant; and
a chiller configured to supply the coolant to the heat exchanger.

6. The organic solvent supplying apparatus of claim 5, wherein the cooling module further comprises a temperature controller configured to control a flow rate of the coolant supplied to the heat exchanger.

7. The organic solvent supplying apparatus of claim 6, wherein the temperature controller controls the flow rate of the coolant on the basis of the temperature of the organic solvent supplied to the substrate.

8. The organic solvent supplying apparatus of claim 7, wherein the temperature of the organic solvent is measured by a temperature sensor provided in the nozzle.

9. The organic solvent supplying apparatus of claim 1, wherein the organic solvent supplied in a cooled state is dissolved by a supercritical fluid in the supercritical processing chamber.

10. A substrate processing method performed by a substrate processing apparatus, the substrate processing method comprising:
supplying an organic solvent from a liquid processing chamber to a substrate;
transferring the substrate coated with the organic solvent to a supercritical processing chamber; and
supplying a supercritical fluid for drying the organic solvent to the substrate in the supercritical processing chamber,
wherein the organic solvent is supplied to the substrate in a state of being cooled to equal to or less than a predetermined temperature by a cooling module.

11. The substrate processing method of claim 10, wherein the organic solvent comprises isopropyl alcohol (IPA).

12. The substrate processing method of claim 11, wherein the IPA is supplied to the liquid processing chamber at a temperature in a range of −89° C. to 0° C.

13. The substrate processing method of claim 10, wherein the cooling module is provided on a supply line connected to a supply tank for storing the organic solvent and the liquid processing chamber.

14. The substrate processing method of claim 10, wherein the substrate coated with the organic solvent is transferred from the liquid processing chamber to the supercritical processing chamber by a transfer robot.

15. A substrate processing apparatus comprising:
a liquid processing chamber configured to supply an organic solvent for cleaning a substrate to the substrate;
a transfer robot configured to transfer the substrate coated with the organic solvent;
a supercritical processing chamber configured to supply a supercritical fluid for drying the substrate coated with the organic solvent; and
an organic solvent supplying apparatus configured to supply the organic solvent to the liquid processing chamber,
wherein the organic solvent supplying apparatus comprises:
a supply tank configured to store the organic solvent;
a supply line connected to the supply tank and the liquid processing chamber; and
a cooling module provided on the supply line.

16. The substrate processing apparatus of claim 15, wherein the organic solvent comprises isopropyl alcohol (IPA).

17. The substrate processing apparatus of claim 16, wherein the IPA is supplied to the liquid processing chamber at a temperature in a range of −89° C. to 0° C.

18. The substrate processing apparatus of claim 15, wherein the cooling module comprises:
a heat exchanger configured to cool a temperature of the organic solvent to equal to or less than a predetermined temperature using a coolant; and
a chiller configured to supply the coolant to the heat exchanger.

19. The substrate processing apparatus of claim 18, wherein the cooling module further comprises a temperature controller configured to control a flow rate of the coolant supplied to the heat exchanger.

20. The substrate processing apparatus of claim 19, wherein the temperature controller controls the flow rate of the coolant on the basis of the temperature of the organic solvent supplied to the substrate, and
the temperature of the organic solvent is measured by a temperature sensor provided in a nozzle of the liquid processing chamber.
